(19) United States
(12) Patent Application Publication
(10) Pub. No.: US 2015/0029691 A1
(43) Pub. Date: Jan. 29, 2015

(54) DEVICE HOUSING FOR RECEIVING DISPLAY MODULE AND MANUFACTURING METHOD

(71) Applicant: FIH (Hong Kong) Limited, Kowloon (HK)

(72) Inventor: SHIH-WEI YANG, Shindian (TW)

(73) Assignee: FIH (HONG KONG) LIMITED, Kowloon (HK)

(21) Appl. No.: 14/066,950

(22) Filed: Oct. 30, 2013

(30) Foreign Application Priority Data
Jul. 24, 2013 (CN) 2013103119287

(51) Int. Cl. H05K 5/00; B29C 45/14; H05K 5/02

(52) U.S. Cl. CPC H05K 5/0017; H05K 5/0221; B29C 45/14631
USPC 361/807; 264/259

(57) ABSTRACT

A device housing includes a housing body, a support plate, a buffer frame, and a display module. The housing body defines a receiving opening and forms an inner peripheral wall. The housing body is formed around a peripheral wall of the support plate for covering one side of the receiving opening. The buffer frame is formed around the inner peripheral wall of the housing body. The display module is received in the receiving opening and is supported by the support plate. The buffer frame abuts against four sides of the display module.

### BACKGROUND

1. Technical Field

The present disclosure generally relates to device housings, and particularly to a device housing for receiving a display module and a method for manufacturing the device housing.

2. Description of Related Art

Portable electronic devices that have displays incorporated therein, such as mobile phones, laptops, and personal digital assistants, are widely used. The portable electronic device includes a device housing and a display received in the device housing. However, the display is easily damaged if the device is dropped.

To buffer the display, a foam is positioned under the display. However, the foam is not easily precisely aligned in the housing. Additionally, the foam can only buffer the display along a lengthwise direction of the display. If the display is impacted along a widthwise direction, the foam cannot buffer the display.

Therefore, there is room for improvement within the art.

### BRIEF DESCRIPTION OF THE DRAWINGS

Many aspects of the device housing and the method for manufacturing the housing can be better understood with reference to the following drawings. The components in the drawings are not necessarily to scale, the emphasis instead being placed upon clearly illustrating the housing and the method for manufacturing the housing. Moreover, in the drawings, like reference numerals designate corresponding parts throughout the several views.

FIG. 1 is an assembled, schematic view of an exemplary embodiment of a device housing.

FIG. 2 is an exploded, schematic view of the device housing of FIG. 1.

FIG. 3 is a cross-sectional view taken along line III-III of FIG. 1.

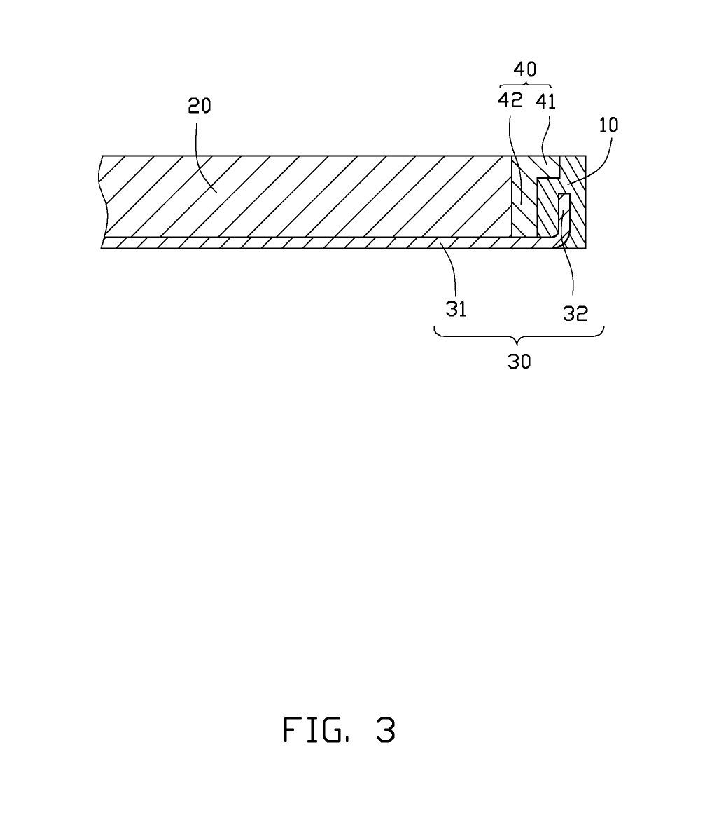

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

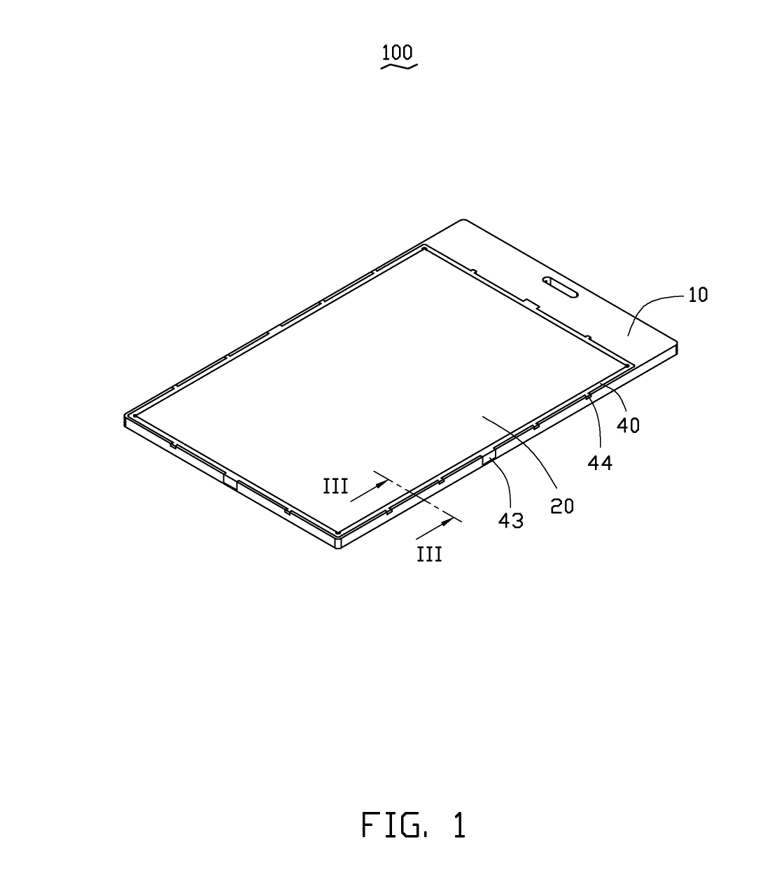

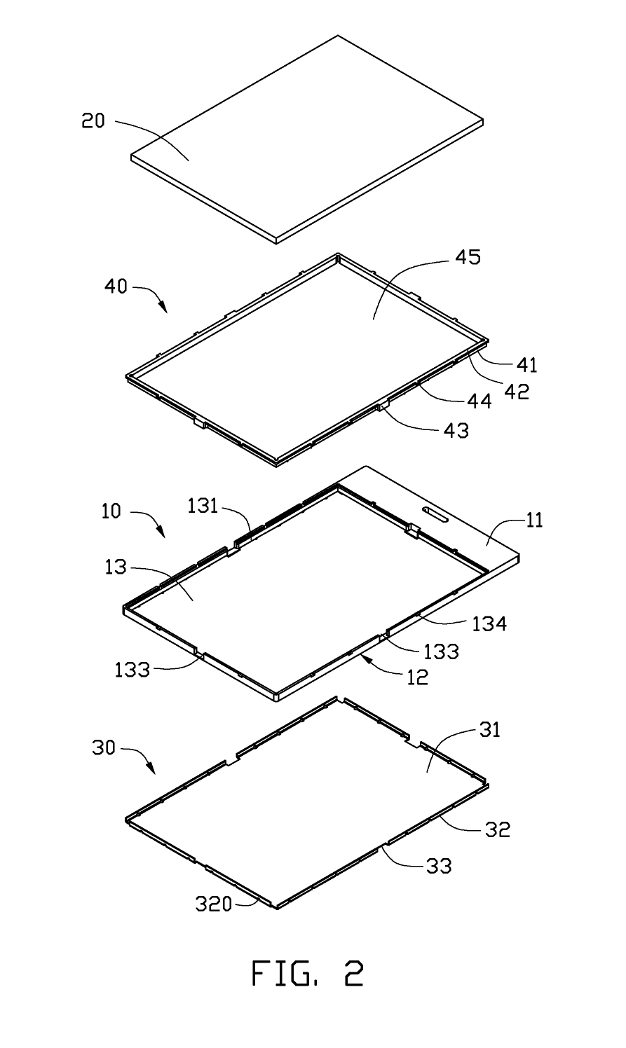

Referring to FIGS. 1-2, a device housing 100 of a portable electronic device includes a housing body 10, a display module 20, a support plate 30, and a buffer frame 40.

The housing body 10 is configured for receiving the display module 20, the support plate 30, and the buffer frame 40. The housing body 10 is made of plastic and formed by injection molding. The plastic can be polycarbonate (PC), or polymethyl methacrylate (PMMA). The housing body 10 includes a first surface 11 and a second surface 12 opposite to each other. A receiving opening 13 is defined in the housing body 10 for receiving the display module 20. A plurality of first latching grooves 133 and a plurality of second latching grooves 134 are defined in the inner peripheral wall 131.

The support plate 30 is made of stainless steel. The support plate 30 has a shape corresponding to a shape of the receiving opening 13. The support plate 30 includes a plate body 31 and a peripheral edge 32. The peripheral edge 32 defines a plurality of through holes 320. The support plate 30 may be embedded into the housing body 10 by forming the housing body 10 around the peripheral edge 32 of the support plate 30 by insert molding to cover one side of the receiving opening 13. Molten plastic flows through the through holes 320 to strengthen a connection between the support plate 30 and the housing body 10. The support plate 30 defines a plurality of notches 33 corresponding to the first latching grooves 133.

The buffer frame 40 is made of elastic material, such as rubber. The buffer frame 40 includes a base portion 41 defining a buffer opening 45. Four extending edges 42 extend out from a top surface of a periphery of the base portion 41. A plurality of first latching blocks 43 and a plurality of second latching blocks 44 are formed on the buffer frame 40. The first latching blocks 43 are latched in the notches 33 and the first latching grooves 133, and the second latching blocks 44 are latched in the second latching grooves 134. In this exemplary embodiment, the first latching blocks 43 extend from the base portion 41 and the extending edges 42, and the second latching blocks 44 extend from the base portion 41.

In assembly, the housing body 10 is formed around the peripheral edge 32 of the support plate 30 by insert molding for covering one side of the receiving opening 13. The notches 33 are aligned with the first latching grooves 133. Then, the buffer frame 40 is formed around a periphery of the receiving opening 13 of the housing body 10. The extending edges 42 abut against the inner peripheral wall 131 of the housing body 10. Finally, the display module 20 is received in the buffer opening 45 of the buffer frame 40 and is supported by the support plate 30. Thus, the device housing 100 is completely assembled.

A method for manufacturing the device housing 100 is described as follows.

Firstly, a stainless steel sheet is provided. The stainless steel sheet is punched to form a support plate 30 having a predetermined shape. A double injection mold is provided. The support plate 30 is placed in a first die chamber of the injection mold to inject molten plastic to form the housing body 10. The molten plastic flows through the through holes 320 of the support plate 30 to improve the connection between the support plate 30 and the housing body 10. After the first injection molding process, the support plate 30 is tightly bonded to the housing body 10. Next, the support plate 30 with the housing body 10 is placed in a second die chamber of the injection mold. Molten rubber flows along the inner peripheral wall 131 of the housing body 10 to form the buffer frame 40. After the second injection molding process, the buffer frame 40 is tightly bonded to the housing body 10 and the support plate 30.

The housing body 10, the support plate 30, and the buffer frame 40 are integrally formed together by the above method. The method for manufacturing the device housing 100 by the injection molding processes increases a production efficiency. Additionally, the display module 20 is supported by the support plate 30, and the buffer frame 40 effectively prevents the display module 20 from being impacted.

It is to be understood, however, that even through numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A device housing comprising:
a housing body defining a receiving opening with an inner peripheral wall;
a support plate formed in the housing body for covering one side of the receiving opening;
a buffer frame formed in the inner peripheral wall of the housing body; and
a display module received in the receiving opening and supported by the support plate;
wherein the buffer frame abuts against four sides of the display module.

2. The device housing as claimed in claim 1, wherein the inner peripheral wall of the housing body defines a plurality of first latching grooves and a plurality of second latching grooves, the support plate defines a plurality of notches corresponding to the first latching grooves, the buffer member defines a plurality of first latching blocks and a plurality of second latching blocks, the first latching blocks are latched into the notches and the first latching grooves, and the second latching blocks are latched into the second latching grooves.

3. The device housing as claimed in claim 2, wherein the support plate includes a plate body and a peripheral edge, and the peripheral edge defines a plurality of through hole.

4. A method for manufacturing a device housing, comprising:
providing a support plate made of metal
injecting a first molten material into a first die chamber of an injection mold to form a housing body bonded to the support plate;
injecting a second molten material into a second die chamber of the injection mold to form a buffer frame bonded to the housing body.
